(19) United States
(12) Patent Application Publication
(10) Pub. No.: US 2010/0162078 A1
(43) Pub. Date: Jun. 24, 2010

(54) TELECOMMUNICATION SYSTEM AND RELATED METHODS

(75) Inventors: Richard Miller, Gilbert, AZ (US); Brian A. Banister, Moscow, ID (US); Patrick Owsley, Moscow, ID (US)

Correspondence Address: BOOTH UDALL, PLC, 1155 W. Rio Salado Pkwy., Suite 101, Tempe, AZ, 85281, US

(73) Assignee: COMTECH EF DATA CORP., Tempe, AZ (US)

(21) Appl. No.: 12/716,988

(22) Filed: Mar. 3, 2010

Related U.S. Application Data
(60) Provisional application No. 61/157,279, filed on Mar. 4, 2009.
(60) Provisional application No. 61/158,226, filed on Mar. 6, 2009.

(51) Int. Cl. H03M 13/29; G06F 11/10; H03M 13/05; H03M 13/19

(52) U.S. Cl. 714/755; 714/752; 714/777; 714/E11.032

(57) ABSTRACT

A telecommunication system and related methods. Implementations may include implementations of a method of encoding data for transmission, including forming a frame by encoding a message block using a short-block low density parity check (LDPC) code and an encoder to form a short encoded block, modulating the short encoded block using a modulation format and a modulator to form a modulated short encoded block, including the modulated short encoded block in a data payload of the frame, and transmitting the frame into a telecommunication channel with a transmitter. The frame may be one of a plurality of frames and each modulated short encoded block in each of the plurality of frames may have a constant number of symbols. The frame may include a modulation/code pair (ModCod) including information relating to the modulation format and the short-block LDPC code used for encoding and modulation.

### CROSS REFERENCE TO RELATED APPLICATIONS

This document claims the benefit of the filing date of U.S. Provisional Patent Application No. 61/157,279, entitled “Adaptive Coding and Modulation System and Related Methods” to Richard Miller which was filed on Mar. 4, 2009, and the benefit of the filing date of U.S. Provisional Patent Application No. 61/158,226, entitled “Telecommunication Block Code,” to Banister et al., which was filed on Mar. 6, 2009, the disclosures of which are hereby incorporated entirely herein by reference.

### BACKGROUND

1. Technical Field

Aspects of this document relate generally to telecommunication systems and techniques for encoding and modulating information for transmission through a telecommunication channel.

2. Background Art

Conventional telecommunications systems have been devised that include a modulator and forward error correction (FEC) encoder that can change either modulation type (order) or FEC encoder rate, or both. A specific nomenclature has emerged to describe a combination of a modulation type and code rate, i.e., ModCod (also referred to as Mod/Code). In implementations of conventional systems employing ModCod, the modulator sends the value of the ModCod to signal to the demodulator/decoder how to configure for the correct modulation type and FEC code rate during the demodulation/decoding process. This is the basis for Adaptive Coding and Modulation (ACM).

### SUMMARY

Implementations of telecommunication systems like those disclosed in this document may include implementations of a transmission system for encoding and modulating data for transmission across a telecommunication channel. Implementations of the system may include an encoder adapted to receive a message block from a quantity of data to be included in a data payload of a frame of a plurality of frames and to encode the quantity of data using a short-block low density parity check (LDPC) code or any other forward error correction block code, including, but not limited to Turbo Product Coding (TPC) to form a short encoded block. The system may also include a modulator coupled to the encoder and adapted to receive the short encoded block, to modulate the short encoded block using a modulation format to form a modulated short encoded block that includes a plurality of symbols, and to include the modulated short encoded block in a data payload included in the frame. The system may also include a transmitter coupled to the modulator and adapted to send the frame into the telecommunication channel where each modulated short encoded block in the data payload of each of the plurality of frames has a constant number of symbols and where each frame of the plurality of frames includes a preamble including a modulation/code pair (ModCod) including information relating to the modulation format and the short-block LDPC code or any other forward error correction block code, including, but not limited to Turbo Product Coding (TPC) used to encode the message block and to modulate the short encoded block.

Implementations of a transmission system for encoding and modulating data for transmission across a telecommunication channel may include one, all, or any of the following:

The message block may have a block size between about 1 kilobit and about 9 kilobits.

The modulation format may comprise (but is not limited to) binary phase shift keying (BPSK), quadrature phase shift keying (QPSK), or quadrature amplitude modulation (QAM).

The short-block LDPC code may have a code rate between about 0.4 to about 0.9.

The ModCod in each preamble may be selected from a group of twelve ModCods or twelve pairs of ModCods.

The message block may have a block size between about 1 kilobit and about 9 kilobits; the short-block LDPC code has a code rate between about 0.4 to about 0.9; the modulation format may be selected from the group consisting of binary phase shift keying (BPSK), quadrature phase shift keying (QPSK), and quadrature amplitude modulation (QAM); and the ModCod in each preamble may be selected from a group of twelve ModCods or twelve pairs of ModCods.

The ModCod may be encoded as a non-linear block code, where the first codeword has a first distance spectrum.

The system may further include a second frame with a preamble including a second ModCod included in a second codeword of the non-linear block code, where the second codeword has a second distance spectrum different from the first distance spectrum.

The ModCod and an overhead channel bit value may be included in a first codeword of a first pair of codewords of the non-linear block code, and a second frame of the plurality of frames may include a preamble including a ModCod and an overhead channel bit value included in a second codeword of the first pair of codewords of non-linear block code, where the first codeword has a first Hamming distance to the second codeword and the first pair of codewords has a second Hamming distance to a second pair of codewords of the non-linear block code where the second Hamming distance is larger than the first Hamming distance.

The short-block LDPC code may be a non-interleaved short-block LDPC code adapted to reduce the end-to-end latency of a telecommunication system utilizing the transmission system.

Implementations of telecommunication systems like those disclosed in this document may utilize implementations of a method of encoding data for transmission across a telecommunication channel. The method may include forming a frame of a plurality of frames by encoding a message block from a quantity of data to be included in a data payload of the frame using a short-block low density parity check (LDPC) code and an encoder to form a short encoded block and modulating the short encoded block using a modulation format and a modulator to form a modulated short encoded block. The method may also include including the modulated short encoded block in the data payload of the frame and transmitting the frame of the plurality of frames into a telecommunication channel with a transmitter where each modulated short encoded block included in the plurality of frames has a constant number of symbols and where each frame of the plurality of frames includes a preamble including a modulation/code pair (ModCod) including information relating to the modulation format and the short-block LDPC code used to encode the message block and modulate the short encoded block.

Implementations of a method of encoding data for transmission across a telecommunication channel may include one, all, or any of the following:

Encoding the message block from the quantity of data may further include encoding a message block with a block size between about 1 kilobit and about 9 kilobits.

Modulating the short encoded block using the modulation format and the modulator may further include modulating with a modulation format selected from the group consisting of (but not limited to) binary phase shift keying (BPSK), quadrature phase shift keying (QPSK), and quadrature amplitude modulation (QAM).

Encoding the message block from the quantity of data may further include encoding with a short block LDPC code having a code rate between about 0.4 to about 0.9.

Forming the frame of the plurality of frames may further include selecting one of twelve ModCods and using the modulation format and short-block LDPC code indicated by the selected ModCod to perform the encoding of the message block and the modulation of the short encoded block.

Encoding the message block from the quantity of data may further include encoding the message block with a block size between about 1 kilobit and about 9 kilobits and encoding the message block with a short-block LDPC code having a code rate between about 0.4 to about 0.9; modulating the short encoded block using the modulation format may further include modulating with a modulation format selected from the group consisting of binary phase shift keying (BPSK), quadrature phase shift keying (QPSK), and quadrature amplitude modulation (QAM); and forming the frame of the plurality of frames may further include selecting one of twelve ModCods and using the modulation format and short-block LDPC code indicated by the selected ModCod to perform the encoding of the message block and the modulation of the short encoded block.

Forming the frame of the plurality of frames may further include encoding the ModCod in a first codeword of a non-linear block code, the first codeword having a first distance spectrum, and including the first codeword in the preamble of the frame.

The frame may be a first frame of the plurality of frames, the short encoded block may be a first short encoded block, and the modulated short encoded block may be a first modulated short encoded block and the method may further include forming a second frame of the plurality of frames by encoding a second message block from a quantity of data to be included in a data payload of the second frame using short-block LDPC code and the encoder to form a second short encoded block, modulating the second short encoded block using the modulation format and the modulator to form a second modulated short encoded block, and including the second modulated short encoded block in the data payload of the second frame. The method may also include forming a preamble including a second ModCod including information relating to the modulation format and the LDPC code used to encode the second message block and to modulate the second short encoded block. The second ModCod may be encoded in a second codeword of the non-linear block code, where the second codeword has a second distance spectrum different from the first distance spectrum.

Encoding the ModCod in the first codeword of non-linear block code, may further include including an overhead channel bit value in the first codeword where the overhead channel bit value is configured to transport data associated with an overhead channel of a telecommunication system.

Encoding the message block from the quantity of data may further include reducing the end-to-end latency of a telecommunication system by encoding with a systematic, non-interleaved short-block LDPC code.

Implementations of telecommunication systems like those disclosed in this document may utilize implementations of a method of encoding data for transmission across a telecommunication channel. The method may include forming a frame by encoding and modulating a message block from a quantity of data to be included in a data payload of the frame using a modulation format and a short-block LDPC code associated with a modulation/code pair (ModCod) selected from a table of ModCods:

| | | | Message Block Size |
|---|---|---|---|
| ModCod | Modulation | Code Rate | (bits) |
| 0 | BPSK | 0.488 | 2k |
| 1 | QPSK | 0.533 | 4.1k |
| 2 | QPSK | 0.631 | 4.1k |
| 3 | QPSK | 0.706 | 4.1k |
| 4 | QPSK | 0.803 | 4.1k |
| 5 | 8-QAM | 0.642 | 6.1k |
| 6 | 8-QAM | 0.711 | 6.1k |
| 7 | 8-QAM | 0.780 | 6.1k |
| 8 | 16-QAM | 0.731 | 8.2k |
| 9 | 16-QAM | 0.780 | 8.2k |
| 10 | 16-QAM | 0.829 | 8.2k |
| 11 | 16-QAM | 0.853 | 8.2k |

The method may further include transmitting the frame into a telecommunication channel with a transmitter.

Implementations of telecommunication systems like those disclosed in this document may utilize implementations of a method of transmitting data using adaptive coding and modulation (ACM). The method may include forming a first frame of a plurality of frames by encoding a first message block from a quantity of data to be included in a data payload of the first frame using a first short-block LDPC code and an encoder to form a first short encoded block, modulating the first short encoded block using a first modulating format and a modulator to form a first modulated short encoded block, and including the first modulated short encoded block in the data payload of the first frame. The method may also include forming a first preamble including a first codeword including a first ModCod and an overhead channel bit value where the ModCod includes information relating to the first modulation format and the first short-block LDPC code used to encode the first message block and to modulate the first modulated short encoded block and where the overhead channel bit value is adapted to transmit data relating to one or more channel quality metrics through an overhead channel. The method also includes transmitting the first frame of the plurality of frames into a telecommunication channel with a transmitter, receiving data relating to one or more channel quality metrics through the overhead channel, and determining that at least one of the modulation format and the short-block LDPC code used to form frames of the plurality of frames subsequent to the first frame should be changed using the data relating to the one or more channel quality metrics. The method may also include forming a second frame of a plurality of frames by encoding a second message block from a quantity of data to be included in a data payload of the second frame using a second short-block LDPC code and the encoder to form a second short encoded block, modulating the second short encoded block using a second modulation format and the modulator to form a second modulated short encoded block where at least one of the second short-block LDPC code and the second modulation format may be different from the respective first short-block LDPC code and the first modulation format. The method may also include including the second modulated short encoded block in the data payload of the second frame and forming a second preamble including a second codeword including a second ModCod and a second overhead channel bit value where the second ModCod includes information relating to the second modulation format and the second short-block LDPC code used to encode the second message block and to modulate the second modulated short encoded block where the second ModCod is different than the first ModCod and where the second overhead channel bit value is adapted to transmit data relating to one or more channel quality metrics through the overhead channel. The method may also include transmitting the second frame of the plurality of frames into the telecommunication channel with a transmitter and where the first modulated short encoded block in the first frame and the second modulated short encoded block in the second frame have the same number of symbols.

Implementations of a method of transmitting data using adaptive coding and modulation may include one, all, or any of the following:

Forming the first preamble including the first codeword may further include selecting the first codeword from a, non-linear block code, the first codeword having a first distance spectrum, and forming the second preamble including the second codeword may further include selecting the second codeword from the-, non-linear block code, the second codeword having a second distance spectrum different from the first distance spectrum.

Forming the first preamble including the first codeword may further include selecting the first codeword from a first pair of codewords of a non-linear block code and forming the second preamble including the second codeword may further include selecting the second codeword from the first pair of codewords of a non-linear block code where the first codeword has a first Hamming distance to the second codeword and the first pair of codewords has a second Hamming distance to a second pair of codewords of the non-linear block code where the second Hamming distance is larger than the first Hamming distance.

Encoding the first message block and encoding the second message block may both further include reducing the end-to-end latency of a telecommunication system by encoding using a systematic, non-interleaved short-block LDPC code.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a diagram of the portions of an implementation of a frame arranged in various positions in the data sequence of the frame;

FIG. 2 is a block diagram view of an implementation of a transmission system and of an implementation of a receiving system in communication through a telecommunication channel;

FIG. 3 is a chart of the required signal-to-noise ratio (SNR) for a bit error rate (BER) of 5*10⁻⁸ for the implementations of ModCods illustrated in Table 1 versus the Shannon bound;

FIG. 4 is flowchart of an implementation of a method of encoding data for transmission across a telecommunication channel;

FIG. 5 is a flowchart of an implementation of method of transmitting data using adaptive coding and modulation;

FIG. 6 contains diagrams of the operation of an encoder when a systematic rate ½, a systematic rate ⅞, and a non-systematic code are encoded, illustrating resulting encoder latencies;

### DESCRIPTION

This disclosure, its aspects and implementations, are not limited to the specific components or assembly procedures disclosed herein. Many additional components and assembly procedures known in the art consistent with the intended telecommunication system and/or assembly procedures for a telecommunication system will become apparent for use with particular implementations from this disclosure. Accordingly, for example, although particular implementations are disclosed, such implementations and implementing components may comprise any shape, size, style, type, model, version, measurement, concentration, material, quantity, and/or the like as is known in the art for such telecommunication systems and implementing components, consistent with the intended operation.

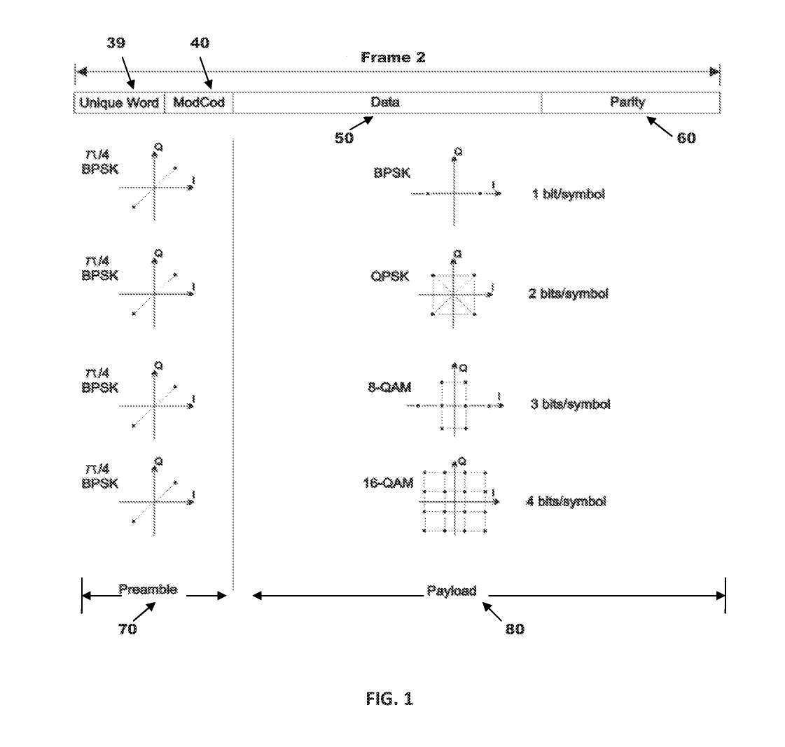

Referring to FIG. 1, an implementation of a frame 2 is illustrated. The frame 2 includes a data sequence and various portions of the data sequence include data set aside for specific purposes. For example, a preamble 70 portion may include a unique word 39 and a ModCod 40. The unique word 39 is used for receiver synchronization and ambiguity resolution based on its use by a demodulator 16 to identify the start of the data sequence of the frame 2. In some implementations, the preamble 70 portion may not be utilized, however. The frame 2 also includes a data payload 80 that includes a quantity of data that is being carried by the frame 2. Encoding algorithms, like Forward Error Correction (FEC) encoding algorithms, may be used to ensure that the quantity of data included in the data payload 80 can be recovered from the data payload 80 even if part of the data payload 80 cannot be decoded due to the influence of distortion and noise in the telecommunication channel 12 that the frame 2 passes through from the transmitter 10 to the receiver 14. When FEC type codes are used, the frame 2 includes a parity 60 portion used by the demodulator 16 to determine the extent of errors and corruption in the data carried by the frame 2 caused by distortion and noise. The size of the parity 60 portion is determined by various parameters of the FEC code type utilized to perform the encoding, including the code rate. The code rate represents a ratio of the actual bits of data included in the data payload 80 to the number of redundant bits of data included in the parity 60 portion. When the code rate is lower, the particular FEC code implementation utilized to encode the data in the data payload 80 is referred to as a stronger code, since it provides more protection for the data transported.

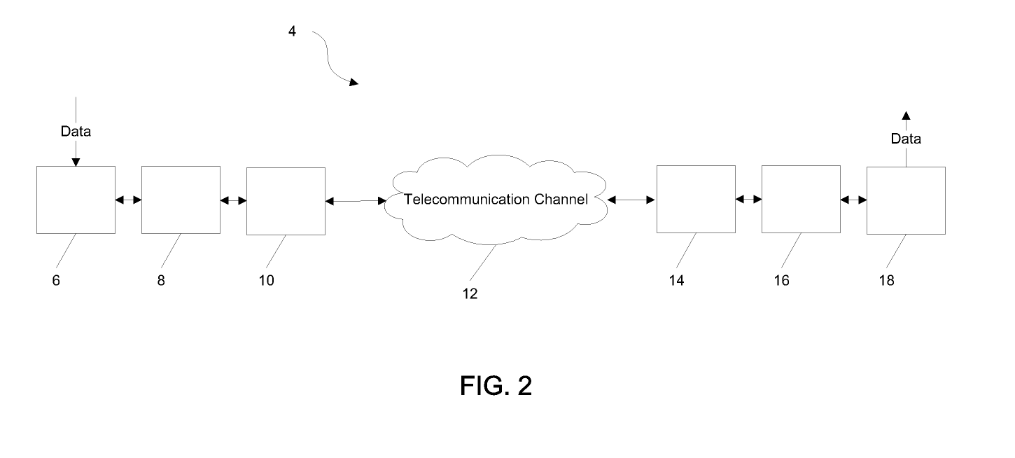

Referring to FIG. 2, an implementation of a telecommunication system 4 is illustrated. On the transmit side, an encoder 6 receives data to be encoded and encodes it using a particular FEC code implementation (which is most likely to be a block code, but not limited as such), passing the encoded data to modulator 8 for modulation using a particular modulation format to form a frame including a plurality of symbols. The resulting frame is then passed to transmitter 10 which sends the frame, carried by a carrier wave, into telecommunication channel 12. The frame then passes through the telecommunication channel 12, carried by the carrier wave, until it is received by receiver 14 and the encoded data carried by the frame recovered from the carrier wave by demodulator 16. Demodulator 16 uses the plurality of symbols in the frame and the ModCod 40 information in the frame to demodulate the data payload 80 portion of the frame 2 and pass the resulting encoded data to decoder 18, which then decodes the encoded data thereby recovering the quantity of data being transported in the data payload 80.

Referring to FIGS. 1 and 2, the quantity of data included in the data payload 80 of the frame 2 (and each subsequent frame for a plurality of frames), is divided into discrete messages (message blocks), each the specified size of the block used by the particular implementation of the code. Those FEC codes that encode message blocks are referred to as block codes. Once a particular message block from the quantity of data has been identified as one to be included in the data payload 80, an encoder 6 encodes it using the parameters (including a desired code rate) of the desired FEC block code to form an encoded block (made up of one or more codewords of the block code). When the block code is systematic, a parity 60 portion is appended to the end of the data sequence of the frame 2. In some implementations of frame 2 implementations, interleaving of the message block may be utilized. When a systematic code is interleaved, the data from the message block that otherwise would be found in the parity 60 portion is interleaved throughout the resulting encoded block. Where codes using interleaving are utilized, the encoded block requires de-interleaving prior to decoding.

After the encoding, the encoded block is modulated using a modulator 8 and a particular modulation format to form a modulated encoded block. The modulation can take place by mapping the bits of the encoded block (which may include one or more codewords) to symbols in a particular symbol constellation using a symbol mapper to assign bit values to corresponding symbol positions in the I/Q plane or through use of any of a wide variety of conventional modulation techniques. Examples of modulation formats that may be utilized by particular implementations of telecommunication systems like those disclosed in this document include, by non-limiting example, binary phase shift keying (BPSK), quadrature phase shift keying (QPSK), quadrature amplitude modulation (QAM), and any other modulation format type such as amplitude and phase shift keying (APSK). Information relating to the modulation format and various parameters of the block code used to encode the message block (including the code rate in particular implementations) may be represented as a modulation/code pair, or ModCod 40, and included in the data sequence of the frame 2 in the preamble 70 portion of the data sequence of the frame 2.

In particular implementations, the ModCod 40 (i.e., the data corresponding with the ModCod 40) may be included or encoded in a codeword of the block code, either as part of an encoded block or as an entire encoded block. The ModCod 40 is used by the demodulator 16 and decoder 18 to demodulate and decode the encoded block(s) included in the data payload 80. In many implementations, the ModCod 40 itself is modulated and encoded using a different modulation format and block code implementation than those used to modulate and encode the data payload 80 itself, though they may be the same in some implementations. Any of a wide variety of modulation format types and block code types disclosed in this document may be employed to encode the ModCod 40 and/or the preamble 70 portion of the frame 2, including π/4 BPSK. π/4 BPSK is defined in this case as ‘normal’ BPSK that has been rotated by π/4 radians, or 45 degrees, relative to the I axis in the I/Q complex plane, such that equal power is observed in both I and Q.

A wide variety of block code types may be utilized by particular implementations of telecommunication systems like those disclosed in this document. In the implementations disclosed in this document, low-density parity check (LDPC) codes are used, though in other implementations, other FEC block code types, such as Turbo Product Codes (TPC)—may also be utilized. The size in bits of the message blocks used with the LDPC codes utilized ranges from about 1 kilobit to about 9 kilobits. Because of this, the LDPC code implementations disclosed in this document are referred to as short-block LDPC codes. In addition, the size in bits of the modulated encoded blocks used with the LDPC codes is not necessarily constant in particular implementations; rather, the size in symbols of the modulated encoded block(s) included in each frame is kept constant in symbols rather than constant in bits. Because the modulated encoded blocks are constant in symbols, a corresponding reduction in the complexity of the demodulator may be realized and improved synchronization capabilities may also be observed in particular implementations along with reduced encoder latency. Because each block is kept constant in symbols, the actual number of bits transported per modulated encoded block (or per modulated codeword) in the data payload 80 of each frame 2 can vary from frame to frame, according to which ModCod 40 is used. The code rates utilized by particular implementations of short-block LDPC codes like those disclosed in this document may range from about 0.4 to about 0.9.

The short-block LDPC code used to encode the payload 80 is a binary linear code, where the number of codewords in the code is a power of two, and the addition of each additional information bit to be carried by the codewords of the code increases the number of codewords by a factor of two. In a linear block code, each codeword has a distance spectrum, or set of Hamming distances to all of the other codewords in the block code. In a linear code, all of the codewords have the same distance spectrum, or set of Hamming distances to each other. Another way of stating the relationship is that in a linear code, the minimum Hamming distance in the distance spectrum of each codeword is the same. Because of this, the distance spectrum can be referred to in terms of the complete set of Hamming distances in the distance spectrum or in terms of the minimum Hamming distance of the distance spectrum.

The non-linear block code used to encode the ModCod 40 in one in which at least one codeword (a first codeword) has a first distance spectrum that is different than a distance spectrum of one or more other codewords (a second codeword) included in the non-linear block code. Because of this, the minimum Hamming distance of the first distance spectrum may be larger or smaller than the minimum Hamming distance of the second distance spectrum. Where the minimum Hamming distance of the first distance spectrum is larger than the Hamming distance of the second distance spectrum, the first codeword may be said to be stronger than the second codeword. This is because the first codeword differs from the second codeword (and all other codewords that have the same second distance spectrum) by more bit positions and is, therefore, less likely to be mistakenly identified during the decoding process as any codeword having the second distance spectrum. In some implementations utilizing non-linear block codes, the codewords may be arranged in pairs, where the first codeword of a first pair has a first Hamming distance to the second codeword of the first pair and the first pair has a second Hamming distance to a second pair of codewords. In particular implementations, the second Hamming distance may be larger than the first Hamming distance, meaning that the first codeword and second codeword are more likely to be mistakenly identified as each other than as either of the codewords included in the second pair.

Where paired codewords are used, the ModCod 40 and an overhead channel bit value may be included in one of the paired codewords, where only the overhead channel bit value differs between the pair of codewords. The overhead channel bit value may be used to transport data for an overhead channel included in the particular telecommunication system implementation. The overhead channel may carry a wide variety of information used by the telecommunication system, including, by non-limiting example, channel quality metrics, control parameters, changes in modulation and/or code type, or any other desired value useful for operating the telecommunication system. The overhead channel provides essential feedback from the receiver to the transmitter in an ACM system. Because the overhead channel bit values are included in the codewords that form the frame itself, the overhead channel data passes through the same telecommunication channel as the data in the data payload 80. Additionally, including the overhead data in the ModCod 40 substantially increases the error protection than if the overhead data were to be transmitted in the data payload 80 itself. Additional disclosure regarding additional implementations of non-linear block codes, codewords, codeword pairs, and overhead channel bit values and related methods may be found in U.S. patent application Ser. No. 12/714,224 to Owsley et al., entitled “Telecommunication Block Code,” filed Feb. 26, 2010, the disclosure of which is hereby incorporated entirely herein by reference.

For the exemplary purposes of this disclosure, the characteristics, structure, and use of an implementation of a short-block LDPC code and corresponding ModCods 40 are disclosed herein. Many other implementations of short-block LDPC codes (both non-linear and linear) and corresponding ModCods 40 are possible using the principles disclosed in this document. Table 1 includes the set of ModCods 40 and corresponding parameters and performance characteristics associated with a particular implementation of a short-block LDPC code:

TABLE 1

| | | | | Message | | | Modem end- |
|---|---|---|---|---|---|---|---|
| | | | Spectral | Block size, | Measured | | to-end latency |
| | | Code | efficiency, | data + | Eb/No, in | Equivalent | at 64 kbps, |
| ModCod | Modulation | Rate | bps/Hz | parity bits | dB | SNR (dB) | milliseconds |
| 0 | BPSK | 0.488 | 0.49 | 2k | 2.4 | −0.7 | 26 |
| 1 | QPSK | 0.533 | 1.07 | 4.1k | 2.2 | 2.5 | 53 |
| 2 | QPSK | 0.631 | 1.26 | 4.1k | 2.8 | 3.8 | 59 |
| 3 | QPSK | 0.706 | 1.41 | 4.1k | 3.4 | 4.9 | 62 |
| 4 | QPSK | 0.803 | 1.61 | 4.1k | 3.9 | 6.0 | 66 |
| 5 | 8-QAM | 0.642 | 1.93 | 6.1k | 4.5 | 7.4 | 89 |
| 6 | 8-QAM | 0.711 | 2.13 | 6.1k | 5.1 | 8.4 | 93 |
| 7 | 8-QAM | 0.780 | 2.34 | 6.1k | 5.7 | 9.4 | 97 |
| 8 | 16-QAM | 0.731 | 2.93 | 8.2k | 6.1 | 10.8 | 125 |
| 9 | 16-QAM | 0.780 | 3.12 | 8.2k | 6.6 | 11.5 | 129 |
| 10 | 16-QAM | 0.829 | 3.32 | 8.2k | 7.4 | 12.6 | 131 |
| 11 | 16-QAM | 0.853 | 3.41 | 8.2k | 7.9 | 13.2 | 132 |

As shown in Table 1, twelve ModCods 40 are utilized, however, one having ordinary skill in the art will recognize that more than twelve ModCods 40 may also be utilized. For example, when an overhead bit is transmitted, the number of ModCods 40 doubles and thus, rather than utilizing twelve ModCods 40, twelve pairs of ModCods are utilized as a result of the overhead bit transmission. The Measured Eb/No values are calculated for a 5*10⁻⁸ bit error rate (BER) and include the data preamble 70 added to each frame 2. The resulting end-to-end latency values for all twelve ModCods 40 range from 26 msec to 132 msec at 64 kilobits per second. The choice of 8-QAM rather than 8-PSK (phase shift keying) as the modulation format for ModCods 5, 6, and 7 was driven by the observations that channel quality characteristics are known to be difficult to track when 8-PSK is used in an adaptive coding and modulation implementation. In adaptive coding and modulation (ACM), the modulation format and/or the code rate (ModCod) are changed in response to information about the quality metrics of the telecommunication channel through which the data is being transmitted. When low values of the signal to noise ratio (SNR) are known to exist in a telecommunication channel, for 8-PSK to be used, additional pilot symbols may be sent through the channel to allow for correct tracking in the carrier recovery loop of the demodulator which increases the demodulator complexity. In particular implementations, a modified BPSK phase detector may be utilized for carrier tracking in conjunction with modulation using 8-QAM that results in carrier tracking at values 3-4 dB lower than when 8-PSK is used. Additional information regarding systems and methods that utilize 8-QAM may be found in U.S. Pat. No. 7,254,188 to Cannon and Miller, entitled “Method and System for Modulating and Detecting High Datarate Symbol Communications,” issued Aug. 7, 2007, the disclosure of which is hereby incorporated herein by reference.

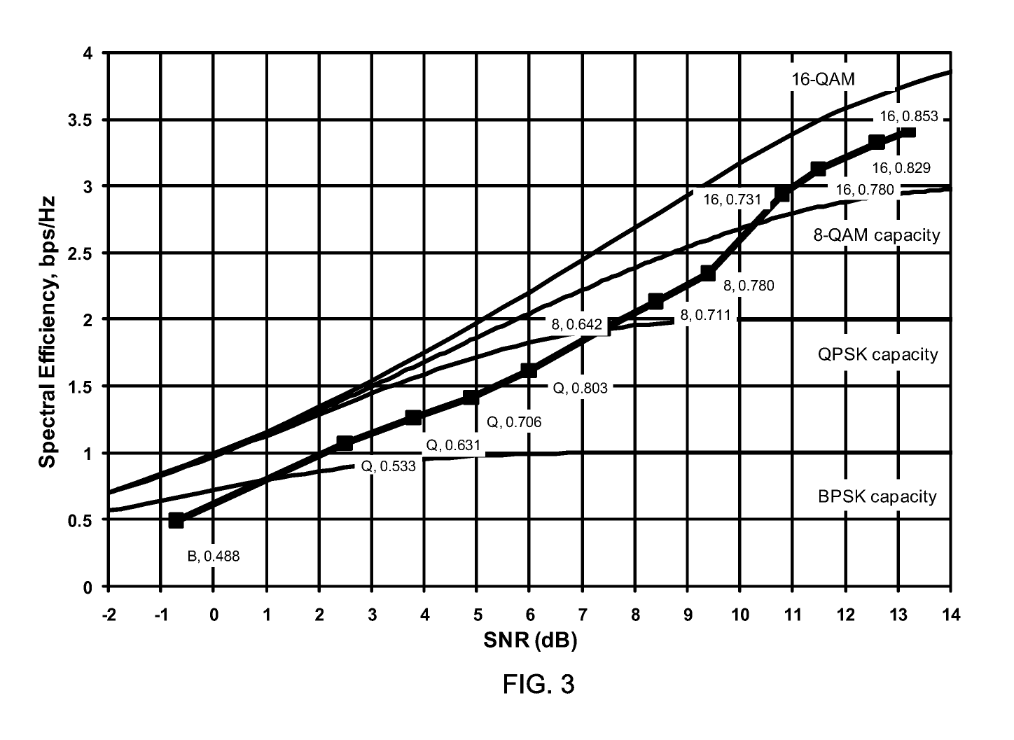

Referring to FIG. 3, a graph of the required SNR versus the Shannon bound for a BER of 5*10⁻⁸ for the ModCod 40 implementations shown in Table 1 is illustrated. As shown the performance is between about 1.0 and about 2.0 dB of the bound. The ModCods 40 also provide an almost uniform progression of spectral efficiency (in bps/Hz) with increasing SNR. This characteristic of the ModCods 40 of Table 1 may make them useful for utilization in an implementation of a telecommunication system that utilizes ACM. The performance illustrated in FIG. 3 is also achieved without using a concatenated BCH code as is the case with DVB-S2, as detailed in the European Telecommunications Standards Institute (ETSI) specification EN 302307, March 2005, herein incorporated by reference.

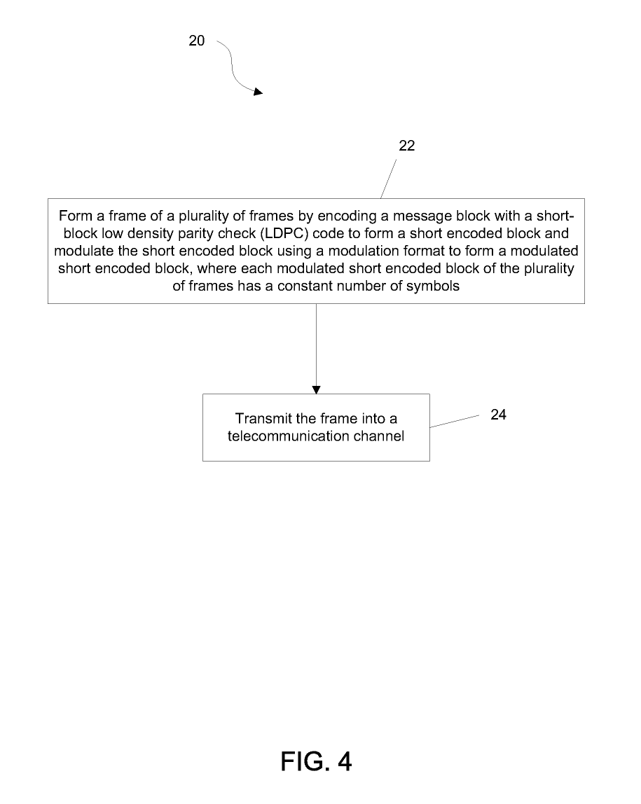

Referring to FIG. 4, implementations of telecommunication systems like those disclosed in this document may utilize implementations of a method of encoding data for transmission across a telecommunication channel 20. As illustrated, implementations of the method 20 may include forming a frame of a plurality of frames by encoding a message block with a short-block LDPC code to form a short encoded block and modulating the short encoded block using a modulation format to form a modulated short encoded block, where each modulated short encoded block of the plurality of frames has a constant number of symbols per block (step 22) and transmitting the frame into a telecommunication channel (step 23). Any of the ModCod 40 implementations, code rates, modulation formats, message block sizes, and systematic, non-interleaved short-block LDPC codes disclosed in this document may be utilized in various implementations of the method. In particular, implementations of the method may employ various implementations of non-linear block codes to allow for unequal protection of the ModCods 40 in the data frames by encoding them in codewords of different strengths having different distance spectra. Also implementations of the method may enable transmission of data through an overhead channel by using pairs of codewords from a non-linear block code implementation that include overhead channel bit values.

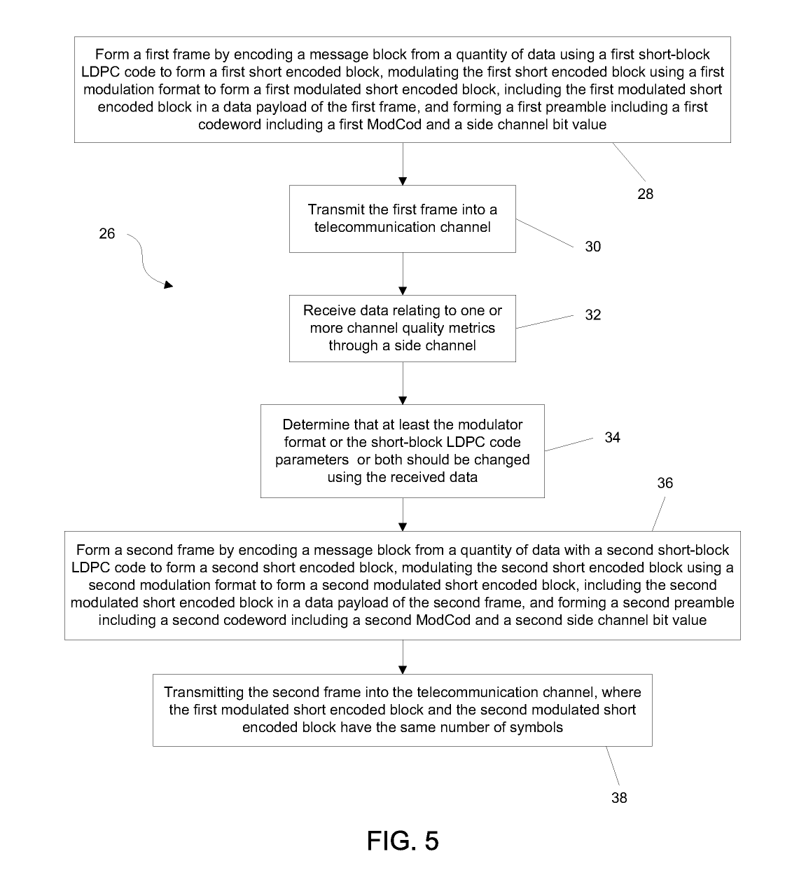

Referring to FIG. 5, implementations of telecommunication systems like those disclosed in this document may utilize implementations of a method of transmitting data using adaptive coding and modulation 26. As illustrated, the method 26 includes forming a first frame by encoding a message block from a quantity of data using a first short-block LDPC code to form a first short encoded block, modulating the first short encoded block using a first modulation format to form a first modulated encoded block, including the first modulated short encoded block in a data payload of the first frame, and forming a first preamble including a first codeword including a first ModCod and an overhead channel bit value (step 28). The method 26 also includes transmitting the first frame into a telecommunication channel (step 30), receiving data relating to one or more channel quality metrics through an overhead channel (step 32), and determining that at least the modulator format or the short-block LDPC code parameters or both should be changed using the received data (step 34). The method 26 may include forming a second frame by encoding a message block from a quantity of data with a second short-block LDPC code to form a second short encoded block, modulating the second short encoded block using a second modulation format to form a second modulated short encoded block, including the second modulated short encoded block in a data payload of the second frame, and forming a second preamble including a second codeword including a second ModCod and a second overhead channel bit value (step 36). The method 26 also includes transmitting the second frame into the telecommunication channel, where the first modulated short encoded block and the second modulated short encoded block have the same number of symbols (step 38). As with the method of encoding data for transmission across a telecommunication channel 20, implementations of the method 26 may employ any of the ModCod implementations, and short-block LDPC codes, systematic or otherwise, disclosed in this document.

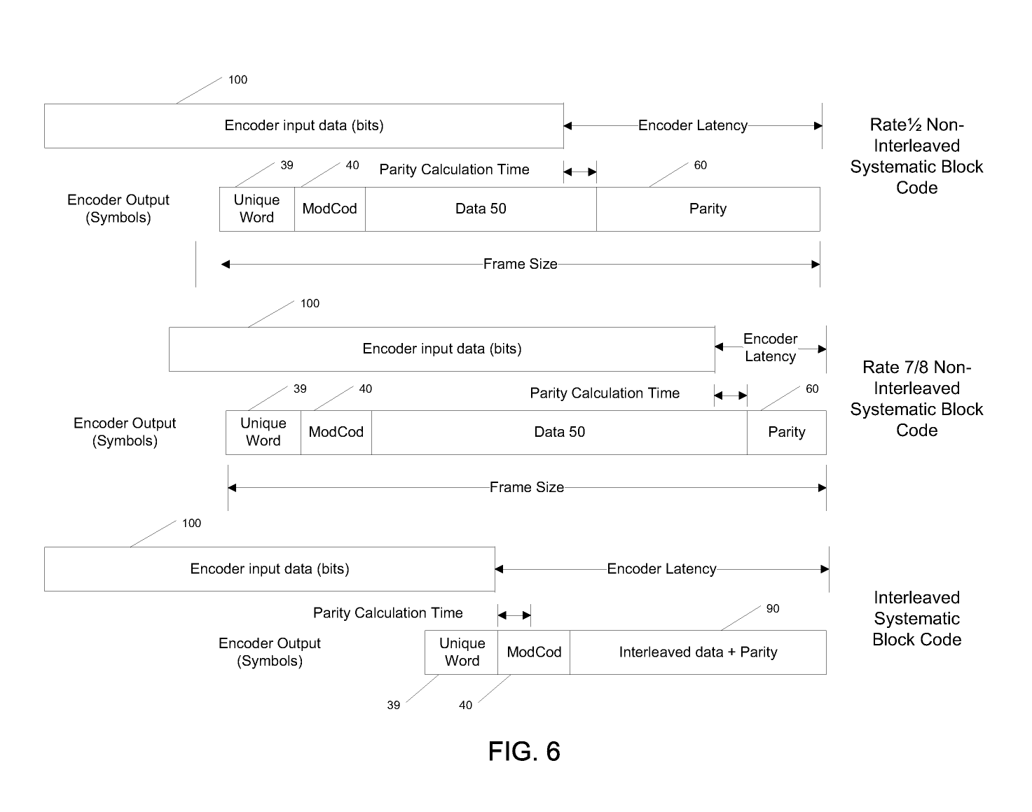

Referring to FIG. 6, implementations of three different block codes are illustrated, showing the relationship between the amount of data encoded (the size of the message block) and the resulting size of the data payload (which contains one or more modulated encoded blocks or codewords), along with the latency of each block code type. The behaviors of the rate 1/2 non-interleaved systematic block code and the rate 7/8 non-interleaved systematic block code are compared in FIG. 6 with a conventional interleaved block code. An example of a conventional interleaved block code is disclosed in the Digital Video Broadcasting-Satellite-Second Generation (DVB-S2) specification (EN 302307). Such a block code format has been utilized in an ACM satellite telecommunication system application by Hughes Network Systems of Germantown, Md. In the DVB-S2 specification, two block sizes are used, 64,800 bits (64 k blocks), or 16,200 bits (16 k blocks). Twenty-four ModCods are defined in the specification, and three of the four modulation formats utilize interleaving. The DVB-S2 specification does not include any provisions for an overhead or side channel.

In systems employing block codes, a minimum latency can be calculated from the input of the encoder 6 to the output of the decoder 18. The overall end-to-end latency is the sum of the latency at the encoder 6 and the latency at the decoder 18. On the decoder side, the latency is the sum of the decoding time plus the time required to receive a block of data (as an encoded block). For any block code, whether interleaving is employed or not, the decoder 18 needs to receive an entire block before the decoding process can begin. If the speed of the processing clock is assumed to be much faster than the data rate, the decoding time (even if many iterations may be required), becomes minimal. As the clock speed increases, the decoding time approaches zero. Therefore, the asymptotic bound for minimum decoder latency is the time to receive one block of data, or one encoded block.

On the encoder side, determining the theoretical minimum latency depends upon more factors, including whether the code being used is a systematic, non-interleaved or an interleaved code. Referring to FIG. 6, inspection of the non-systematic or interleaved block code diagram indicates that because the parity bits are calculated after all of the input data is received [the message block(s)], the block of interleaved data+parity bits 90 cannot start to be formed until after the parity calculation time. Accordingly, the encoding of the entire block of data waits until after the parity calculation time. As the parity calculation time approaches zero, the asymptotic bound of the encoder latency approaches the time required to encode a block of input data 100 (a message block or blocks) to produce an encoded block. Accordingly, because of the nature of an interleaved block code, like the DVB-S2 block codes, the encoder latency can be no smaller than one encoded block (corresponding to one message block). Because the limit of the decoder latency is one encoded block, for interleaved FEC block codes, like those used in the DVB-S2 standard, the minimum end-to-end latency of the telecommunication system is two encoded blocks. The minimum encoder latency for a non-systematic or interleaved code may be represented mathematically by the formula 1*(Frame Size).

Referring to FIG. 6, for the two examples of non-interleaved systematic codes, the asymptotic bound for encoded latency is (1−Code Rate) blocks. This is because in a non-interleaved systematic code, the parity information 60 does not have to be interleaved within the encoded information 50, but is appended at the end. This allows the encoder 6 to begin outputting the preamble 70 portion and/or the encoded data 50 in the data payload 80 prior to receiving the entire amount of input data 100 (as a message block or blocks). As illustrated, when higher rate codes are used, the encoder 6 can begin outputting the preamble 70 and/or the encoded data 50 in the data payload 80 sooner than when lower rate codes are used. Because of this, as the code rate approaches one (or no parity bits are included), the latency of the encoder 6 approaches zero for a non-interleaved systematic code, which is different from the non-systematic or interleaved case. The latency of an encoder 6 using a systematic block code can be represented as (1−Code Rate)*(Frame Size). Accordingly, the end-to-end latency of a telecommunication system employing a high code rate systematic, non-interleaved block code asymptotically approaches half that of a telecommunication system employing a non-systematic or interleaved block code at the same code rate. Accordingly, implementations of telecommunication systems like those disclosed in this document that utilize the systematic non-interleaved short-block LDPC codes disclosed herein have a lower latency that telecommunication systems utilizing DVB-S2 specified block codes at similar code rates.

In implementations of telecommunication systems disclosed in this document that employ ACM, the latency of the system will be the latency resulting from the use of the ModCod 40 having the highest impact on latency (i.e., the one with the lowest rate or other parameter impacting latency). This ModCod 40 may be referred to as the worst-case ModCod. For example, when an ACM system implementation starts the transmission and reception of data using a ModCod 40 using a systematic block code, the system operates at the end-to-end latency of a systematic block code, meaning that message blocks of data flow into the encoder 6, and encoded blocks flow out, with a latency approaching (1−Code Rate)blocks. In particular implementations, the modulator 8 requires that symbols flow through it in a smooth, uninterrupted fashion at an exact, fixed rate. When the ModCod 40 changes to a lower code rate, and a message block of data enters the encoder where the latency (based on (1−Code Rate)blocks) is suddenly higher, a gap in the encoded block data being sent to the modulator 8 will exist until the encoder 6 finishes encoding the message block. This gap is not tolerated by the modulator 8, so to prevent the existence of the gap, particular implementations of ACM systems identify the ModCod 40 with the worst-case latency, and artificially add a delay to the other ModCods 40 that provide less than the worst-case latency, so that, regardless of the ModCod 40 used, encoded data 50 always flows out of the encoder 6 to the modulator 8 without gaps. Accordingly, the set of ModCods 40 with the smallest worst-case latency will provide any telecommunication system utilizing that set a lower latency than a telecommunication system using set of ModCods 40 with a higher worst-case latency.

Referring to Table 2, the latency for the set of ModCods 40 illustrated in Table 1 at a fixed 100 ksymbols/sec rate is displayed. The end-to-end latency of a telecommunication system employing the set of ModCods 40 is calculated as (2−Code Rate) blocks. While the ModCods 40 span a 7:1 variation in throughput, the latency varies only between 25 to 34 milliseconds. Without being bound by any theory, it is believed that a careful analysis indicates that this is an effect of using a constant number of symbols per encoded block, along with using a systematic non-interleaved block code implementation. The worst case latency in an ACM situation using this set of ModCods 40 is 34 milliseconds.

TABLE 2

| | | Code | Bit rate, kbps | End-to-end |
|---|---|---|---|---|
| ModCod | Modulation | Rate | (throughput) | Latency |
| 0 | BPSK | 0.488 | 49 | 34 |
| 1 | QPSK | 0.533 | 107 | 32 |
| 2 | QPSK | 0.631 | 126 | 30 |
| 3 | QPSK | 0.706 | 141 | 28 |
| 4 | QPSK | 0.803 | 161 | 26 |
| 5 | 8-QAM | 0.642 | 193 | 30 |
| 6 | 8-QAM | 0.711 | 213 | 28 |
| 7 | 8-QAM | 0.780 | 234 | 27 |
| 8 | 16-QAM | 0.731 | 293 | 27 |
| 9 | 16-QAM | 0.780 | 312 | 26 |
| 10 | 16-QAM | 0.829 | 332 | 25 |
| 11 | 16-QAM | 0.853 | 341 | 25 |

Table 3 includes calculations for a telecommunication system operating at 100 ksymbols/sec and similar code rates using codes from the DVB-S2 specification and a 16 k block size.

TABLE 3

| | | | Latency, based on 2 blocks |
|---|---|---|---|
| | | | (asymptotic bound for |
| | Code | Bit rate, kbps | minimum latency with an |
| Modulation | Rate | (throughput) | interleaved code) |
| QPSK | 0.49 | 98 | 329 |
| QPSK | 0.66 | 132 | 244 |
| QPSK | 0.74 | 148 | 218 |
| QPSK | 0.89 | 179 | 180 |
| 8-PSK | 0.66 | 198 | 163 |
| 8-PSK | 0.74 | 222 | 145 |
| 8-PSK | 0.89 | 267 | 121 |
| 16-APSK | 0.66 | 264 | 122 |
| 16-APSK | 0.74 | 296 | 109 |
| 16-APSK | 0.83 | 330 | 98 |
| 16-APSK | 0.89 | 355 | 91 |

By inspection, a consequence of having a constant number of bits per block (and the use of interleaved codes) as is specified in the DVB-S2 specification (besides increased demodulator complexity) is increased system latency. In the DVB-S2 implementations illustrated in Table 3, each time the ModCod 40 is lowered and the throughput reduced, the latency increases accordingly because the block size is related to data rate, not symbol rate. Because in particular implementations of ACM systems disclosed in this document the system latency is equal to the latency of the worst-case ModCod 40, the DVB-S2 system shows a severe penalty compared to the telecommunication system utilizing the set of ModCods 40 in Table 2: 329 milliseconds of latency versus 34 milliseconds. Accordingly, in various implementations of ACM systems disclosed in this document, the worst-case end-to-end latency may be approximately one order of magnitude lower than an ACM system employing ModCods 40 from the DVB-S2 specification at the same symbol rate.

In places where the description above refers to particular implementations of telecommunication systems and block codes, it should be readily apparent that a number of modifications may be made without departing from the spirit thereof and that these implementations may be applied to other telecommunication and block code implementations.

1. A method of encoding data for transmission across a telecommunication channel, the method comprising:
forming a frame of a plurality of frames by:
encoding a message block from a quantity of data to be included in a data payload of the frame using a short-block low density parity check (LDPC) code and an encoder to form a short encoded block;
modulating the short encoded block using a modulation format and a modulator to form a modulated short encoded block; and
including the modulated short encoded block in the data payload of the frame; and
transmitting the frame of the plurality of frames into a telecommunication channel with a transmitter;
wherein each modulated short encoded block included in the data payload of each of the plurality of frames has a constant number of symbols; and
wherein each frame of the plurality of frames includes a preamble including a modulation/code pair (ModCod) including information relating to the modulation format and the short-block LDPC code used to encode the message block and modulate the short encoded block.

2. The method of claim 1, wherein encoding the message block from the quantity of data further comprises encoding a message block with a block size between about 1 kilobit and about 9 kilobits.

3. The method of claim 1, wherein modulating the short encoded block using the modulation format and the modulator further comprises modulating with a modulation format selected of binary phase shift keying (BPSK).

4. The method of claim 1, wherein modulating the short encoded block using the modulation format and the modulator further comprises modulating with a modulation format of quadrature phase shift keying (QPSK).

5. The method of claim 1, wherein modulating the short encoded block using the modulation format and the modulator further comprises modulating with a modulation format of quadrature amplitude modulation (QAM).

6. The method of claim 1, wherein encoding the message block from the quantity of data further comprises encoding with a short block LDPC code having a code rate between about 0.4 to about 0.9.

7. The method of claim 1, wherein forming the frame of the plurality of frames further comprises selecting one of twelve ModCods and using the modulation format and short-block LDPC code indicated by the selected ModCod to perform the encoding of the message block and the modulation of the short encoded block.

8. The method of claim 1, wherein encoding the message block from the quantity of data further comprises encoding a message block with a block size between about 1 kilobit and about 9 kilobits and encoding the message block with a short-block LDPC code having a code rate between about 0.4 to about 0.9;
wherein modulating the short encoded block using the modulation format further comprises modulating with a modulation format selected from the group consisting of binary phase shift keying (BPSK), quadrature phase shift keying (QPSK), and quadrature amplitude modulation (QAM); and
forming the frame of the plurality of frames further comprises selecting one of twelve ModCods and using the modulation format and the short-block LDPC code indicated by the selected ModCod to perform the encoding of the message block and the modulation of the short encoded block.

9. The method of claim 1, wherein forming the frame of the plurality of frames further comprises encoding the ModCod in a first codeword of a non-linear block code, the first codeword having a first distance spectrum, and including the first codeword in the preamble of the frame.

10. The method of claim 9, wherein the frame is a first frame of the plurality of frames and the short encoded block is a first short encoded block and the modulated short encoded block is a first modulated short encoded block, and the method further comprises:
forming a second frame of the plurality of frames by:
encoding a second message block from a quantity of data to be included in a data payload of the second frame using the short-block LDPC code and the encoder to form a second short encoded block;
modulating the second short encoded block using the modulation format and the modulator to form a second modulated short encoded block;
including the second modulated short encoded block in the data payload of the second frame; and
forming a preamble including a second ModCod including information relating to the modulation format and the LDPC code used to encode the second message block and to modulate the second short encoded block;
wherein the second ModCod is encoded in a second codeword of the non-linear block code, the second codeword having a second distance spectrum; and
wherein the first distance spectrum is different than the second distance spectrum.

11. The method of claim 9, wherein encoding the ModCod in the first codeword of the non-linear block code further comprises including an overhead channel bit value in the first codeword where the overhead channel bit value is configured to transport data associated with an overhead channel of a telecommunication system.

12. The method of claim 1, wherein encoding the message block from the quantity of data further comprises reducing the end-to-end latency of a telecommunication system by encoding with a non-interleaved systematic short-block LDPC code.

13. A method of encoding data for transmission across a telecommunication channel, the method comprising:
forming a frame by encoding and modulating a message block from a quantity of data to be included in a data payload of the frame using a modulation format and a short-block LDPC code associated with a modulation/code pair (ModCod) selected from a table of ModCods,

| | | | Message Block Size |
|---|---|---|---|
| ModCod | Modulation | Code Rate | (bits) |
| 0 | BPSK | 0.488 | 2k |
| 1 | QPSK | 0.533 | 4.1k |
| 2 | QPSK | 0.631 | 4.1k |
| 3 | QPSK | 0.706 | 4.1k |
| 4 | QPSK | 0.803 | 4.1k |
| 5 | 8-QAM | 0.642 | 6.1k |
| 6 | 8-QAM | 0.711 | 6.1k |
| 7 | 8-QAM | 0.780 | 6.1k |
| 8 | 16-QAM | 0.731 | 8.2k |
| 9 | 16-QAM | 0.780 | 8.2k |
| 10 | 16-QAM | 0.829 | 8.2k |
| 11 | 16-QAM | 0.853 | 8.2k |

14. The method of claim 13, further comprising transmitting the frame into a telecommunication channel with a transmitter.

15. A method of transmitting data using adaptive coding and modulation, the method comprising:
forming a first frame of a plurality of frames by:
encoding a first message block from a quantity of data to be included in a data payload of the first frame using a first short-block low density parity check (LDPC) code and an encoder to form a first short encoded block;
modulating the first short encoded block using a first modulation format and a modulator to form a first modulated short encoded block;
including the first modulated short encoded block in the data payload of the first frame; and
forming a first preamble including a first codeword including a first ModCod and an overhead channel bit value, the ModCod including information relating to the first modulation format and the first short-block LDPC code used to encode the first message block and to modulate the first modulated short encoded block, and the overhead channel bit value adapted to transmit data relating to one or more channel quality metrics through an overhead channel; and
transmitting the first frame of the plurality of frames into a telecommunication channel with a transmitter;
receiving data relating to one or more channel quality metrics through the overhead channel;
determining that at least one of the modulation format and the short-block LDPC code used to form frames of the plurality of frames subsequent to the first frame should be changed using the data relating to the one or more channel quality metrics;
forming a second frame of the plurality of frames by:
encoding a second message block from a quantity of data to be included in a data payload of the second frame using a second short-block LDPC code and the encoder to form a second short encoded block;
modulating the second short encoded block using a second modulation format and the modulator to form a second modulated short encoded block wherein at least one of the second short-block LDPC code and the second modulation format is different from the respective first short-block LDPC code and the first modulation format;
including the second modulated short encoded block in the data payload of the second frame; and
forming a second preamble including a second codeword including a second ModCod and a second overhead channel bit value, the second ModCod including information relating to the second modulation format and the second short-block LDPC code used to encode the second message block and to modulate the second modulated short encoded block, where the second ModCod is different than the first ModCod, and where the second overhead channel bit value is adapted to transmit data relating to one or more channel quality metrics through the overhead channel; and
transmitting the second frame of the plurality of frames into the telecommunication channel with a transmitter;
wherein the first modulated short encoded block in the first frame and the second modulated short encoded block in the second frame have the same number of symbols.

16. The method of claim 15, wherein forming the first preamble including the first codeword further comprises selecting the first codeword from a non-linear block code, the first codeword having a first distance spectrum, and wherein forming the second preamble including the second codeword further comprises selecting the second codeword from the non-linear block code, the second codeword having a second distance spectrum, wherein the first distance spectrum is different from the second distance spectrum.

17. The method of claim 15, wherein forming the first preamble including the first codeword further comprises selecting the first codeword from a first pair of codewords of a non-linear block code and wherein forming the second preamble including the second codeword further comprises selecting the second codeword from the first pair of codewords of a non-linear block code wherein the first codeword has a first Hamming distance to the second codeword and the first pair of codewords has a second Hamming distance to a second pair of codewords of the non-linear block code where the second Hamming distance is larger than the first Hamming distance.

18. The method of claim 15, wherein encoding the first message block and wherein encoding the second message block both further comprise reducing the end-to-end latency of a telecommunication system by encoding using a systematic non-interleaved short-block LDPC code.

19. A transmission system for encoding and modulating data for transmission across a telecommunication channel, the transmission system comprising:
an encoder adapted to receive a message block from a quantity of data to be included in a data payload of a frame of a plurality of frames and to encode the message block using a short-block low density parity check (LDPC) code to form a short encoded block;
a modulator coupled to the encoder and adapted to receive the short encoded block; to modulate the short encoded block using a modulation format to form a modulated short encoded block, the modulated short encoded block comprising a plurality of symbols; and to include the modulated short encoded block in a data payload included in the frame; and
a transmitter coupled to the modulator and adapted to send the frame into the telecommunication channel;
wherein each modulated short encoded block in the data payload of each of the plurality of frames has a constant number of symbols; and
wherein each frame of the plurality of frames includes a preamble including a modulation/code pair (ModCod) comprising information relating to the modulation format and the short-block LDPC code used to encode the message block and to modulate the short encoded block.

20. The system of claim 19, wherein the message block has a block size between about 1 kilobit and about 9 kilobits.

21. The system of claim 19, wherein the modulation format is selected from the group consisting of binary phase shift keying (BPSK), quadrature phase shift keying (QPSK), and quadrature amplitude modulation (QAM).

22. The system of claim 19, wherein the short-block LDPC code has a code rate between about 0.4 to about 0.9.

23. The system of claim 19, wherein the ModCod in each preamble is selected from a group of twelve ModCods or twelve pairs of ModCods.

24. The system of claim 19, wherein the message block has a block size between about 1 kilobit and about 9 kilobits; the short-block LDPC code has a code rate between about 0.4 to about 0.9; the modulation format is selected from the group consisting of binary phase shift keying (BPSK), quadrature phase shift keying (QPSK), and quadrature amplitude modulation (QAM); and the ModCod in each preamble is selected from a group of twelve ModCods or twelve pairs of ModCods.

25. The system of claim 19, wherein the short-block LDPC code is a non-interleaved short-block LDPC code and the ModCod is encoded in a first codeword of the non-linear block code, the first codeword having a first distance spectrum.

26. The system of claim 25, further comprising a second frame with a preamble comprising a second ModCod encoded in a second codeword of the non-linear block code, the second codeword having a second distance spectrum wherein the first distance spectrum is different than the second distance spectrum.

27. The system of claim 19, wherein the short-block LDPC code is a non-interleaved short-block LDPC code and the ModCod and an overhead channel bit value are included in a first codeword of a first pair of codewords of the non-linear block code and a second frame of the plurality of frames includes a preamble including a ModCod and an overhead channel bit value included in a second codeword of the first pair of codewords of the non-linear block code wherein the first codeword has a first Hamming distance to the second codeword and the first pair of codewords has a second Hamming distance to a second pair of codewords of the non-linear block code where the second Hamming distance is larger than the first Hamming distance.

28. The system of claim 19, wherein the short-block LDPC code is a systematic, non-interleaved short-block LDPC code adapted to reduce the end-to-end latency of a telecommunication system utilizing the transmission system.
